(19) United States
(12) Patent Application Publication
(10) Pub. No.: US 2007/0187701 A1
(43) Pub. Date: Aug. 16, 2007

(54) Compact multi-LED light source with improved heat dissipation

(76) Inventors: Wooi Kin Goon, Penang (MY); Eng Chuan Ong, Penang (MY); Meng Ee Lee, Penang (MY)

Correspondence Address: Kathy Manke;Avago Technologies Limited, 4380 Ziegler Road, Fort Collins, CO, 80525, US

(21) Appl. No.: 11/357,276

(22) Filed: Feb. 16, 2006

(51) Int. Cl. H01L 33/00

(52) U.S. Cl. 257/88

(57) ABSTRACT

A light source having a substrate having first and second surfaces is disclosed. The substrate has first and second conducting traces on the first surface. A heat conducting metallic layer is attached to the second surface. First and second LEDs are disposed on the first surface, each LED having first and second contacts for powering that LED. The first contact is connected to a corresponding one of the first and second conducting traces. First and second conducting vias are in contact with the first and second LEDs, respectively. The first and second conducting vias extend from the first surface through the substrate and contact the heat conducting metallic layer. The second contacts of the first and second LEDs are electrically connected to the first and second conducting vias, respectively. The LEDs are powered by applying potentials between the external terminals and the heat-conducting layer.

### BACKGROUND OF THE INVENTION

Light-emitting diodes (LEDs) are good candidates to replace incandescent and other light sources. LEDs have higher power to light conversion efficiencies than incandescent lamps and longer lifetimes. In addition, LEDs operate at relatively low voltages, and hence, are better adapted for use in many battery-powered devices. Furthermore, LEDs are point sources, and hence, are better adapted than fluorescent sources for lighting systems in which a point light source that is collimated or focused by an optical system is required.

LEDs have two problems that detract from their use in lighting applications. First, LEDs emit light in relatively narrow spectral regions, and hence, to provide a light source having an arbitrary color, a number of LEDs must be combined or some form of phosphor conversion is needed. In a phosphor converted light source, the LED excites a phosphor layer which provides one of the color components needed to provide a source of the desired color. The phosphors are suspended in a layer over the LED. The light losses in this layer due to absorption and scattering are significant, and hence, the LED must provide additional light to make up for these losses. This additional light, in turn, increases the power that must be dissipated by the package.

In principle, a compound light source constructed from three LEDs that emit light in the red, blue, and green regions of the spectrum can generate light that is perceived to be of any color by a human observer by adjusting the relative light output of the three LEDs. To provide such a source and still maintain the point source characteristic discussed above, the three LED chips must be packaged in a small package that efficiently collects the light from the LEDs and mixes the light such that an observer perceives a single “point” source.

Second, to compete with incandescent lights, the LEDs must operate at relatively high power levels, and hence, the LEDs must be packaged in a package that can dissipate a significant amount of heat. Removing this heat from the packaged chips presents a number of problems. As noted above, a very small package is needed to preserve the point source nature of a multiple LED source. In addition, in many applications, cost is a primary concern, and hence, the heat dissipating elements of the package must not substantially increase the cost of the light source. In addition to removing heat, the package must require a minimum number of connections to the surrounding circuitry to reduce the cost of the package and the cost of the components to which the light source is connected.

### SUMMARY OF THE INVENTION

The present invention includes a light source having a substrate with first and second surfaces. The substrate has first and second conducting traces on the first surface. A heat conducting metallic layer is attached to the second surface. The first and second LEDs are disposed on the first surface, each LED having first and second contacts for powering that LED. The first contacts are connected to a corresponding one of the first and second conducting traces. First and second conducting vias are in contact with the first and second LEDs, respectively. The first and second conducting vias extend from the first surface through the substrate and contact the heat conducting metallic layer. The second contacts of the first and second LEDs are electrically connected to the first and second conducting vias, respectively. The light source also includes first and second external terminals disposed on the second surface. The first and second external terminals are connected to the first and second conducting traces, respectively. In one aspect of the invention, the light source optionally includes a thermal mass in contact with the first surface and thermally connected to the heat conducting metallic layer. The thermal mass could include a reflecting cup that extends above the LEDs and reflects light leaving the LEDs. The first LED is powered by applying an electrical potential between the first external terminal and the heat conducting metallic layer, and the second LED is powered by applying a potential between the second external terminal and the heat conducting metallic layer.

### BRIEF DESCRIPTION OF THE DRAWINGS

FIG. 1 is a cross-sectional view of a prior art multi-LED package.

FIG. 2 is a cross-sectional view of a multi-LED package light source according to one embodiment of the present invention.

FIG. 3 is a cross-sectional view of another embodiment of a light source according to the present invention.

FIG. 4 illustrates another embodiment of an LED light source according to the present invention.

### DETAILED DESCRIPTION OF THE PREFERRED EMBODIMENTS OF THE INVENTION

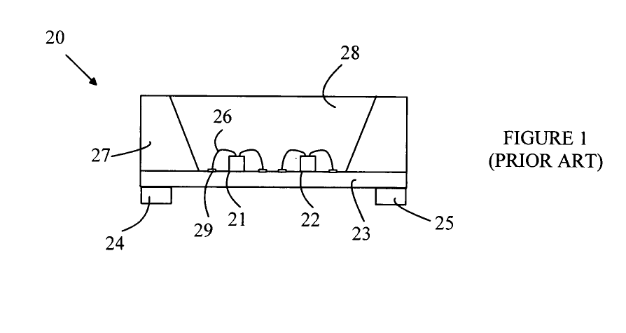

The manner in which the present invention provides its advantages can be more easily understood with reference to FIG. 1, which is a cross-sectional view of a prior art multi-LED package. Package 20 includes two LEDs shown at 21 and 22 that are attached to a substrate 23. Substrate 23 is an insulating substrate having a plurality of conducting traces 29 for providing connections between the LEDs and external circuit terminals such as terminals 24 and 25. The LEDs are connected to the conducting traces by wire bonds 26. The LEDs are located in a reflecting cup 27 having an inner surface that is typically coated with a highly reflective material such as Al. The interior 28 of the cup is typically filled with an encapsulating material that protects the LEDs.

The insulating substrate on which the LEDs are mounted provides electrical insulation for the LEDs; however, the substrate also limits heat flow from the LEDs. In some embodiments, the LEDs are connected individually to heat conducting traces that move heat from the LED to an external heat sink; however, the long heat conducing paths and small cross-sectional area of the heat conducing traces inherent in these designs limit the amount of heat that can be removed from the LEDs.

Single LED packages having heat sinks are also known to the art. The LEDs are connected to the heat sinks by a heat-conducting adhesive. The heat sink is usually external to the LED package and consists of a piece of metal. The size of the heat sink is too large to allow this design to be utilized with multiple LEDs in a single package, since separate electrically isolated heat sinks would be needed for each LED.

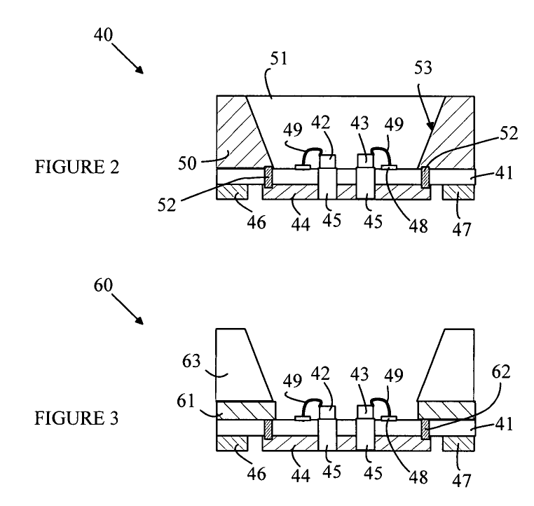

Refer now to FIG. 2, which is a cross-sectional view of a multi-LED package light source 40 according to one embodiment of the present invention. Light source 40 includes the two LEDs shown at 42 and 43. The light source is constructed on a substrate 41 that includes a heat-conducting layer 44 that is affixed to the bottom surface of substrate 41. The LEDs have two power connections. One of the power connections is accessed from the bottom of the LED and connects to a metal filled via 45 that transfers heat from that LED to heat-conducting layer 44. All of the LEDs have this first power connection connected in common by heat conducting layer 44. The current flowing through each LED is controlled by the potential provided on the second power connection. The second power connection of each LED is connected to a conducting trace 48 on substrate 41 by a wire bond connection 49. Each trace, in turn, is connected to an external power terminal. The external power terminals for LEDs 42 and 43 are shown at 46 and 47, respectively. The LEDs are connected to the metal filled vias by a heat-conducting adhesive. The metal filled vias have cross-sectional areas that are sufficient to remove enough heat to maintain the LEDs at a desired operating temperature when the heat-conducting layer is attached to an appropriate heat sink.

In addition to providing increased heat dissipation, light source 40 requires fewer signal connections. Since one of the power leads of each of the LEDs is connected to the common heat conducting layer 44, only N+1 external power terminals are needed for a light source having N LEDs, as opposed to the 2N connections required by conventional configurations.

In applications in which the LEDs are connected in parallel, at most, three external connections are required. One external connection connects the anodes of the LEDs to the power source, and one external connection connects the cathodes of the LEDs to the power source. If the chip is connected to a common heat sink that is not connected to one of the power terminals, a third connection is required to move the heat from the heat conducting layer 44.

Light source 40 can be affixed to a printed circuit board by surface mounting techniques. Heat conducting layer 44 provides a large surface heat connection to the ground plane or other heat-removing surface on the printed circuit board.

Light source 40 can optionally include a reflector assembly 50 having a reflective surface 53 for directing light that leaves the sides of the LED chips in the forward direction. The reflector assembly is constructed from a metal slug in one embodiment of the present invention. The mass of the metal is sufficient to provide a heat sink that increases the thermal mass of the light source. The reflector assembly is thermally connected to heat conducting layer 44 by the metal filled vias shown at 52. In addition to providing increased thermal mass, the outer surfaces of the reflector assembly provide an additional heat dissipation surface. The cavity 51 in the reflecting assembly can be filled with a clear encapsulant to protect the LED dies.

It should be noted that the light reflecting function of reflector assembly 50 and the thermal mass function are separate functions, and hence, one function can be provided without the other or the functions could be provided by separate components. For example, the reflector assembly could be replaced by a thermal mass that does not serve as a reflector. Refer now to FIG. 3, which is a cross-sectional view of another embodiment of a light source according to the present invention. Those elements of light source 60 that serve functions analogous to elements of light source 40 have been given the same numeric designations and will not be discussed in detail here. Light source 60 includes a separate thermal mass 61 that is connected to heat conducting layer 44 by metal filled vias 62. Thermal mass 61 can be a metallic layer deposited on substrate 41 or a separate metal layer that is bonded to substrate 41. A separate metal layer has the advantage of providing a thicker layer than the layers available by conventional plating techniques. It should be noted that a thin metal layer can be attached to substrate 41 and connected to heat conducting layer 44 by the vias. A thicker layer of metal can then be bonded to the thin metal layer to provide the final thermal mass.

A conventional plastic reflecting cup 63 can then be bonded to the thermal mass if a reflector is needed. This arrangement allows for the use of an existing reflecting cup while still providing an enhanced thermal mass for reducing temperature fluctuations in the LEDs.

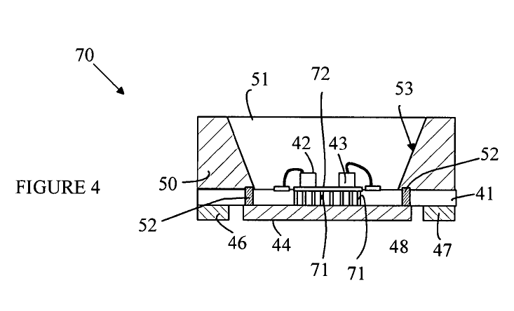

In the embodiments described above, each chip was connected to the heat conducting layer by a single metal filled via. However, embodiments that utilize a number of smaller vias can also be constructed. Refer now to FIG. 4, which illustrates another embodiment of an LED light source according to the present invention. To simplify the following discussion, those elements of light source 70 that serve function analogous to those discussed above with reference to FIG. 2 have been given the same numeric designations and will not be discussed further here.

In light source 70, the LED chips are mounted on a common internal heat conducting layer 72 using a heat conducting adhesive. Heat conducting layer 72 is thermally and electrically connected to heat conducting layer 44 by a plurality of vias 71 that are filled with metal. The total cross-sectional area of vias 71 is sufficient to conduct the heat generated by the LED chips to heat conducting layer 44 while maintaining the temperature of the LED chips at an acceptable level. The additional heat conducting layer 72 also increases the effective thermal mass connected to the LEDs, and hence, reduces any thermal fluctuations to which the LEDs are subjected if the power levels are varied over short periods of time.

Various modifications to the present invention will become apparent to those skilled in the art from the foregoing description and accompanying drawings. Accordingly, the present invention is to be limited solely by the scope of the following claims.

What is claimed is:

1. A light source comprising:
a substrate having first and second surfaces, said substrate having first and second conducting traces on said first surface;
a heat conducting metallic layer attached to said second surface;
first and second LEDs disposed on said first surface, each LED having first and second contacts for powering that LED, said first contact being connected to a corresponding one of said first and second conducting traces;
first and second conducting vias in contact with said first and second LEDs, respectively, said first and second conducting vias extending from said first surface through said substrate and contacting said heat conducting metallic layer, said second contacts of said first and second LEDs being electrically connected to said first and second conducting vias, respectively; and
first and second external terminals disposed on said second surface, said first and second external terminals being connected to said first and second conducting traces.

2. The light source of claim 1 further comprising a thermal mass in contact with said first surface and thermally connected to said heat conducting metallic layer.

3. The light source of claim 2 wherein said thermal mass further comprises a reflecting cup that extends above said LEDs and reflects light leaving said LEDs.

4. The light source of claim 1 wherein said first LED is powered by applying electrical potential between said first external terminal and said heat conducting metallic layer, and said second LED is powered by applying a potential between said second external terminal and said heat conducting metallic layer.
